(19) United States
(12) Patent Application Publication
(10) Pub. No.: US 2015/0243871 A1
(43) Pub. Date: Aug. 27, 2015

(54) HYBRID SOLAR DEVICE FOR PRODUCING ELECTRICITY HAVING AN INCREASED LIFESPAN

(71) Applicant: COMMISSARIAT Á L'ÉNERGIE ATOMIQUE ET AUX ÉNERGIES ALTERNATIVES, Paris (FR)

(72) Inventor: Emmanuel Ollier, Grenoble (FR)

(73) Assignee: Commissariat à l'énergie atomique et aux énergies alternatives, PARIS (FR)

(21) Appl. No.: 14/430,762

(22) PCT Filed: Sep. 25, 2013
(86) PCT No.: PCT/EP2013/069974

§ 371 Date: Mar. 24, 2015

(30) Foreign Application Priority Data
Sep. 26, 2012 (FR) 1259052

(51) Int. Cl. H01L 35/30; H01L 35/32

(52) U.S. Cl. CPC H01L 35/30; H01L 35/32

(57) ABSTRACT

Solar device for generation of electricity comprising a stack including a reception face (2) that will receive a solar flux, a thermoelectric generator (4), said thermoelectric generator (4) comprising at least one thermoelectric module placed between a hot face (6) and a cold face (8), said hot face (6) being located on the same side as the reception face (2), additional heat input means (14) to the hot face (6), said additional heat input means (14) being inserted between the reception face (2) and the hot face (6) of the thermoelectric generator (4), said means (14) comprising a combustion chamber (16) supplied with gas.

### TECHNICAL DOMAIN AND PRIOR ART

This invention relates to a hybrid solar device for producing electricity having an increased lifespan.

There are systems comprising photovoltaic cells converting solar radiation into electricity. However, these systems only operate during the day in the presence of sunshine, i.e. in the presence of solar radiation.

Document KR20100030778 describes a photovoltaic device comprising a solar cell generating current by photoelectric reaction from solar radiation concentrated by a Fresnel lens. The solar cell is fixed on a receiver. A thermoelectric generator is formed on the lower face of the receiver and generates current from the heat produced in the photoelectric cell.

This device has the following disadvantages:
it undergoes temperature variations due to the intermittence of sunshine due to cloudy periods and the day/night alternation. These temperature variations are relatively high and are responsible for very high stresses caused by differences in coefficients of thermal expansion between the different materials. Welded assemblies between thermoelectric elements and connections/supports can then break, reducing reliability,
this device is incapable of providing an approximately constant production of electricity during the day, particularly during cloudy periods and at night;
the thermoelectric generator operates at low temperature, below 100° C., because its temperature is the same as the temperature at the back of the photoelectric cell, therefore its conversion efficiencies are low.

The document “High-performance flat-panel solar thermoelectric generators with high thermal concentration” in Nature Materials Vol. 10, July 2011, pages 532-538 describes a device comprising a solar absorber subject to solar radiation, that is in contact with a thermoelectric generator. It thus forms the heat source of the thermoelectric generator. This device has the same disadvantages as the photoelectric device described above, particularly because its energy source is also intermittent.

### PRESENTATION OF THE INVENTION

Consequently, one purpose of this invention is to provide a device for producing electrical energy from solar radiation with an increased lifespan without being affected by variations due to cloudy periods or day/night alternation so as to generate approximately constant production of electricity 24 hours per day.

The purpose mentioned above is achieved by a solar device comprising one face to which solar radiation will be applied, a thermoelectric generator one face of which will come into contact with a heat source, and an additional heat source, the heat source being formed by the face subject to solar radiation associated with the additional heat source, this source being activated so as to control temperature variations of the heat source, despite for example cloudy periods or a total absence of incident solar radiation.

In other words, production of heat by solar absorption, production of heat by combustion and conversion of this heat into electricity due the thermoelectric effect are integrated into a single device. Due to the production of heat by combustion, constant temperatures or temperatures with a constant gradient can be maintained in the thermoelectric converter, thus improving its reliability. The temperature of the heat source is kept constant and thermal fluxes are kept constant by operation in concentrated solar mode alone, or in combustion mode alone, or in a combined mode, which can give good electricity production efficiency.

In one embodiment, the additional heat source is formed from a combustion chamber located directly between the face subject to solar radiation and the thermoelectric generator.

In another embodiment, the additional heat source is delocalised, heat being transported either by conduction, or by hot combustion gases between the face subject to solar radiation and the thermoelectric generator.

Particularly advantageously, the additional heat is produced by the combustion of hydrogen or a biofuel, for example a biogas. Thus, the device produces electricity solely from renewable energies.

The subject-matter of the present invention is then a solar device for generation of electricity comprising a stack including a face called the reception face that will receive a solar flux, a thermoelectric generator, said thermoelectric generator comprising at least one thermoelectric module placed between a first face called the “hot face” and a second face called the “cold face”, said hot face being located on the same side as the reception face, additional heat input means to the hot face, said additional heat input means being inserted at least partly between the reception face and the hot face of the thermoelectric generator, and means of controlling said additional heat input means.

In one embodiment, the additional heat input means comprise an element located between the reception face and the hot face, said element comprising a combustion chamber supplied with fuel. The combustion chamber may be provided with means of initiating combustion or combustion may be initiated in the combustion chamber directly by the high temperature generated by the solar flux. Advantageously, the combustion chamber comprises channels extending parallel to the hot face of the thermoelectric generator and the reception face.

In another embodiment, the additional heat input means comprise an element located between the reception face and the hot face and provided at least with one channel connected to a combustion chamber supplied with fuel, said chamber comprising means of initiating combustion.

In another embodiment, the additional heat input means comprise an element located between the reception face and the hot face and means of heating said element located outside the stack, said element being provided with an extension projecting laterally from the stack, said extension being designed to be heated by the heating means, the heat input to the hot face being transported by conduction.

Advantageously, the solar electricity generation device comprises means for thermally insulating the lateral extension.

Preferably, the solar device comprises means of applying a tightening force at least between the element and the hot face so as to reduce thermal resistances and to assure mechanical integrity of the device.

The stack may advantageously comprise thermal insulation means between a hot zone of the device formed by the reception face, the additional heat input means and the hot face and a cold zone formed by the cold face.

Heat dissipation means may be provided in contact with the cold face.

Preferably, the reception face comprises a selective high temperature treatment.

In one example embodiment, the additional heat input means comprise an element made from an electrical insulating material, the electrical connections of the thermoelectric generator then being made directly on the element.

For example, the element is made from silicon carbide, molybdenum or tungsten.

The fuel is preferably hydrogen.

Another subject-matter of the present invention is a solar system comprising means of concentrating solar radiation and at least one solar device for generating electricity according to the invention.

In one example embodiment, the solar radiation concentration means consist of a mirror. In another example embodiment, the solar radiation concentration means consist of a Fresnel lens.

The solar system may advantageously comprise means of moving the solar electricity generation device, means of measuring the temperature of the reception face and means of controlling displacement of the device such that the reception face is illuminated by the solar flux.

### BRIEF DESCRIPTION OF THE DRAWINGS

This invention will be better understood after reading the description given below and the appended drawings on which:

FIG. 1 is a diagrammatic side view of one embodiment of a solar device according to the invention;

FIG. 2 is a diagrammatic side view of another embodiment of a solar device according to the invention;

FIGS. 3A and 3B are top and side views respectively of a practical embodiment of the solar device in FIG. 2, in which the thermal interface resistances are reduced;

FIG. 4 is a diagrammatic side view of a variant embodiment of the solar device in FIG. 1;

FIG. 5 is a diagrammatic view of a solar system with concentration by mirrors comprising a device according to the invention;

FIG. 6 is a diagrammatic view of a solar system with concentration by Fresnel lenses comprising a device according to the invention.

### DETAILED PRESENTATION OF PARTICULAR EMBODIMENTS

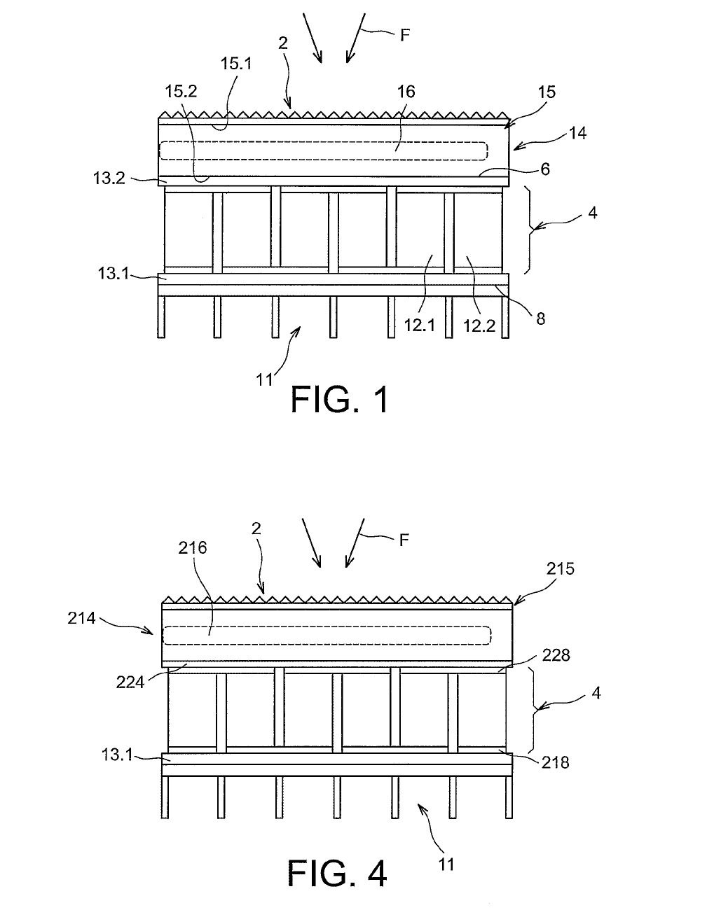

FIG. 1 shows a sectional view of an example of a solar device for producing electricity comprising a face 2 that will receive the solar flux F, preferably concentrated, a thermoelectric generator 4 comprising a first face 6 that will come into contact with a heat source, called the “hot face”, and a second face 8 opposite the face 6 that will come into contact with a cold source, called the “cold face”.

Face 2 will be referred to in the following as the “reception face”. The reception face 2 is heated by the solar flux and at least partly forms the heat source of the thermoelectric generator 4. Preferably, the reception face 2 is such that it is refractory in nature, for example by a special high temperature treatment. This treatment may be applied by physical vapour phase deposition of thin layers or by etching submicronic patterns in the material of element 14.

For the purpose of this application, “thermoelectric generator” means an electricity generator comprising one or several thermoelectric modules connected in series. A thermoelectric generator generates electricity as a result of a “thermoelectric effect” also referred to as the “Seebeck effect”. A potential difference occurs at the junction of two conducting materials with different natures to which a temperature difference is applied.

The thermoelectric generator 4 comprises a substrate and a plurality of modules formed by P-N junctions connected in series. The P-N junctions are formed by an N-doped semiconducting material 12.1 and a P-doped semiconducting material 12.2. The materials 12.1, 12.2 are arranged alternately and extend between the first face 6 and the second face 8. Interconnections are provided between the N-doped materials and adjacent P-doped materials so as to form P-N junctions. The P-N junctions are electrically connected in series.

The materials 12.1, 12.2 from which the P-N junctions are made are separated by the substrate, that is chosen so as to be an electrical insulator to prevent the P-N junctions from being electrically short circuited.

In the example shown, the generator 4 comprises two plates 13.1, 13.2 made from a ceramic material, for example alumina, that provide electrical insulation from the outside and also structural integrity of the generator at high temperature. The inner face of the ceramic plates 13.1, 13.2 may be metallised to make the series connection of the junctions. This embodiment is in no way limitative, as we will see in the remainder of the description.

Heat dissipation or heat routing means 11 are provided in thermal contact with the cold face 8 so as to remove heat from the cold face 8 and thus maintain a temperature differential between the hot face 6 and the cold face 8. For example, these means may consist of a heat sink fitted with fins.

The hot face 6 of the thermoelectric generator 4 is located on the same side as the reception face 2.

The terminals of the thermoelectric generator are electrically connected to electrical storage means such as a battery, and/or directly to a device consuming the generated electrical energy (not shown).

A heat source 14 complementary to the reception face 2 is arranged between the hot face 6 of the thermoelectric generator and the reception face 2.

The heat source 14 comprises an element 15 with a first face 15.1 in contact with the reception face 2 and a second face 15.2 opposite the first face 15.1, in contact with the hot face 6 of the thermoelectric generator. In the example shown, the element 15 comprises a chamber 16 connected to a fuel source (not shown) and provided with means of initiating combustion, forming a combustion chamber. The fuel may be a gas or a liquid, it is preferably a renewable fuel, for example such as a biogas or hydrogen.

Advantageously, the combustion chamber 16 is composed of several channels extending parallel to faces 15.1 and 15.2.

The presence of a material between the channels conducts heat between the reception face 2 and the hot face 6.

Other configurations could be envisaged for heat transfer, for example a single chamber provided with columns for heat conduction could be designed.

Preferably, the reception face 2, the first face 15.1 and the second face 15.2 of the element 15, the hot face 6 and the cold face 8 are parallel.

The element 15 is made from a material with good and preferably very good heat conducting properties, preferably with a heat conductivity of more than 20 W.m⁻¹.K⁻¹, for example such as a metal or metal alloy in order to provide good conduction of heat produced by combustion in the combustion chamber and heat transferred from the reception face 2 heated by the solar flux F. The material can also resist stresses imposed by combustion, for example it may be a refractory metal, or steel or ceramic.

For example the element 15 may be made from SiC or SiSiC.

The element 15 is assembled with the thermoelectric generator such that its face 15.1 is in contact with the hot face 6 of the thermoelectric generator 4.

Preferably, the device comprises means of applying a clamping pressure on the different elements of the device so as to reduce all the thermal resistances at interfaces and increase the reliability of assemblies.

Advantageously, thermal insulation means are provided on the lateral faces of the element 15 so as to limit heat leaks towards the outside and to guide the heat flux towards the hot face of the generator. For example, these means are composed of an insulating material such as zirconia, an aerogel or a vacuum.

We will now describe operation of the device in FIG. 1.

Concentrated solar radiation F is focused on the reception face 2, which has the effect of heating the element 15, which heats the hot face 6 of the thermoelectric generator 4 by thermal conduction.

A temperature differential arises between the hot face 6 and the cold face 8 of the thermoelectric generator generating an electrical current.

Solar radiation disappears when a cloud passes in front of the sun and during the night. Therefore, the reception face 2 no longer receives any solar radiation.

Combustion is then initiated in the combustion chamber 16 of the element 15 causing heating of the walls of the chamber 16 and therefore of the hot face 6. The temperature differential is then maintained in the generator 4 and current is generated continuously even in the absence of solar radiation.

Combustion may be initiated in different ways. The first method consists of introducing combustion gases while the device is still subject to concentrated solar flux.

Thus, the available heat energy can be used to start combustion. The second method may be self-inflammation on catalysts present in the combustion chamber. The third method may be heating of a point in the combustion chamber by an electrical heating resistance.

The combustion mode may be initiated by programming at a fixed time, for example when the sunshine becomes weaker or the incidence of the solar flux decreases, or following detection of a reduction in sunshine measured by an optical detector placed on the module, for example a photovoltaic cell.

If solar radiation is present but is weak, the hot face 6 is heated both by solar radiation through the element 14 and by combustion.

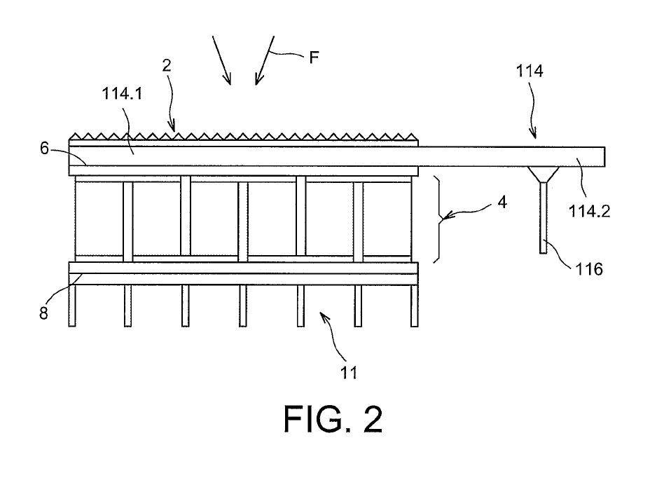

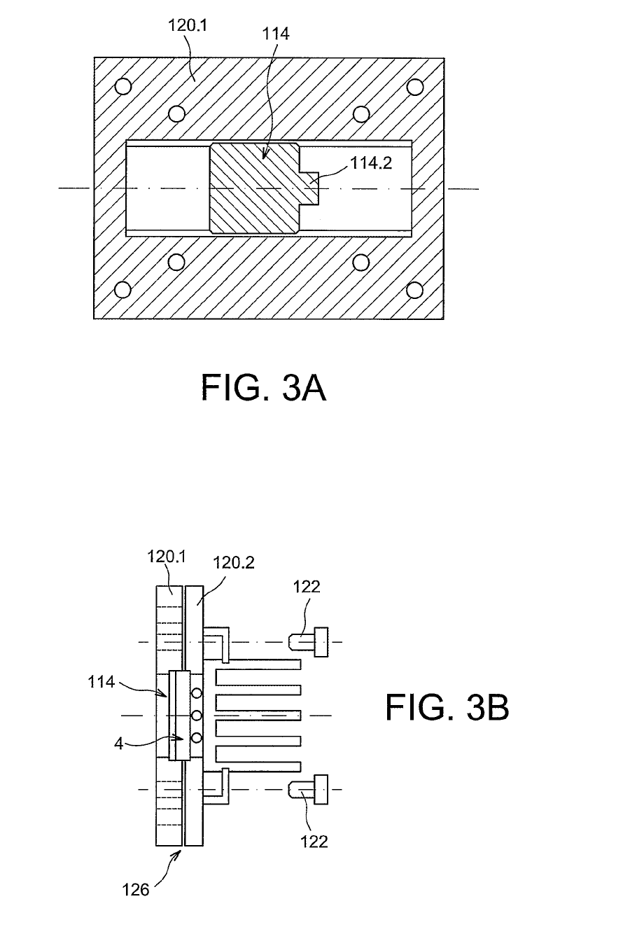

FIG. 2 shows a diagrammatic view of another embodiment of a device according to the invention in which the additional source of thermal energy 114 has been modified and FIGS. 3A and 3B show a practical embodiment of this second embodiment.

In this embodiment, production of thermal energy is located outside the stack. The additional source of thermal energy 114 comprises a part 114.1 inserted between the reception face and the hot face then forming a heat diffuser, a lateral extension 114.2 projecting from the stack through which the diffuser 114.1 is connected to the additional heat production zone 116, routing heat towards part 114.1.

In one example embodiment, the additional heat source is composed of a burner 116 directly heating the lateral extension of the diffuser 114.1 that is then formed from a solid material, heat transfer taking place by heat conduction through the material of the diffuser.

In another embodiment, the additional heat source is composed of a combustion chamber with fluid connections to channels formed in the diffuser, these channels transporting combustion hot gases in the diffuser and providing additional heat input.

The size of the devices may be relatively compact, in this case to produce additional heat, for example micro-burners or micro combustion chambers could be used which are well known to those skilled in the art and will not be described in detail.

Preferably, the combustion chamber is divided into combustion zones by solid material for transferring heat from the receiving surface to the opposite surface that is in contact with the thermoelectric elements. Therefore a micro-combustion chamber with channels is particularly interesting.

The selective high temperature treatment of the reception face may be done directly on the element 114.

Preferably, thermal insulation means (not shown) cover the lateral extension 114.2 so as to limit heat losses. For example, these means are composed of an insulating material such as zirconia, an aerogel or a vacuum.

The diffuser is made from a material that is a good or a very good conductor of heat such as the element 15, for example made from a metal such as molybdenum, or a ceramic such as silicon carbide.

The cold face may for example be in contact with a thermal mass, for example a copper mass, itself in contact with the heat sink. Since copper has very good thermal conductivity of more than 200 W·m⁻¹·K⁻¹, it can make the temperature of the cold face uniform.

In the example shown and advantageously, channels are formed in the copper mass and are connected to a fluid source, fluid circulates in the channels and actively evacuates heat. The presence of these channels is not limitative.

Advantageously and as can be seen in FIGS. 3A and 3B, the stack of the diffuser 114.1 and the thermoelectric generator is held between two end pieces 120.1, 120.2 made from a thermal insulating material, for example made from PEEK (polyetheretherketone) or a zirconia type ceramic.

Furthermore, as was described for the embodiment in FIG. 1, means are advantageously provided capable of applying a clamping force on different elements of the device to bring them into contact with each other. In this example, there are four screws 122 screwed into the two end plates 120.1, 120.2. The clamping force is then applied through two end plates 120.1, 120.2. This example embodiment is not limitative, an additional structure added on top of the end plates fitted with tie rods could be envisaged to apply a tightening force.

As can be seen in FIG. 3B, a space is advantageously provided between the two end plates 120.1, 120.2 to provide thermal insulation between the hot zones and the cold zones to keep a high temperature difference between the hot face 6 and the cold face 8 of the generator 4.

Operation of this device is similar to that in FIG. 1.

Additional heat is added by the diffuser 114.1 to generate electricity in combustion mode alone or in combined mode, by adding an additional heat flux during operation in solar mode.

In solar mode, concentrated radiation is absorbed at the reception face 2 and heats the hot face 6 of the thermoelectric generator 4 through the diffuser 114. The heat sink transfers the heat flux into the environment and thus keeps the cold surface of the generator below a given temperature, for example between −50° C. and 200° C., preferably less than 80° C. The hot face 6 of the generator 4 is kept at a high temperature higher than the temperature of the cold face, for example between 100° C. and 1000° C.

When the concentrated radiation drops or even disappears, additional heat is input through the diffuser 114.1 in order to compensate for the drop in thermal energy through solar radiation. Thus the device may be kept at an approximately constant temperature, so as firstly to increase the reliability of the device and secondly to maintain a high temperature difference between the hot face 6 and the cold face 8 of the generator 4, which enables good efficiency of the thermoelectric generator.

FIG. 4 shows a variant embodiment of the device in FIG. 1.

In this variant, the additional heat source 214 comprises an element 215 provided with a combustion chamber 216 inserted between the reception face 2 and the thermoelectric generator, but the plate made from a ceramic material acting as the support for thermoelectric junctions has been replaced by the additional heat source 214.

In the representation shown in FIG. 4, the material from which element 215 is made is electrically conducting, for example it may be made from SiC, Mo or W, a layer of insulating material 224 also with good heat conducting properties is then inserted between the electrical connections 228 of the thermoelectric junctions and the element 214 so as to isolate the connections of element 215 and prevent a short circuit between the connections. The material used for the insulating layer 224 may for example be alumina (Al₂O₃), aluminium nitride (AlN), boron nitride (BN), etc.

If the element 215 is made from an electrically insulating material, the electrical connections between the thermoelectric junctions may advantageously be assembled directly on the element 215, which improves integration of the device.

As described above for the two other embodiments, means of applying a clamping force are advantageously provided to reduce thermal resistances and to achieve mechanical integrity of the assembly.

The different parts of the devices in each embodiment may be assembled as a function of the materials from which the element 15, 114.1, 215 and the part of the thermoelectric generator in contact with the element 15, 114.1, 215 are made. For example, the assembly may be made by brazing, spot welding or gluing or using a glue or any adhesive material composed of a binder and metal fillers, oxides, nitrides, carbides, to provide good thermal conductivity at the same time as bonding of the assembled surfaces and capable of resisting high temperatures and also providing good heat transfer between the element 15, 114.1, 215 and the hot face 6. For example, the glue is an Aremco series Pyro-Putty® glue.

The thermoelectric generator capable of operating at high temperature may be made using techniques known to those skilled in the art, for example such as the technique described in document WO201071749. The generator described in this document gives good conversion efficiency due to the use of several segments of thermoelectric materials, each adapted to a temperature range. With the invention, it is possible to work more reliably at high temperatures because it prevents repeated temperature increases and decreases. Thus at these high temperatures, the potential of these multi-material thermoelectric structures can be used, and these structures are very interesting in terms of efficiency when the temperature of the hot surface is very high and when the temperature difference between the hot and cold surfaces is very large.

We will now give example dimensions of the device: the side of the reception face is 5 mm to 1 m, preferably 2 cm to 10 cm. The element has approximately the same surface area as the reception face and its thickness may be between 0.5 mm and 10 cm, and preferably between 2 mm and 10 mm.

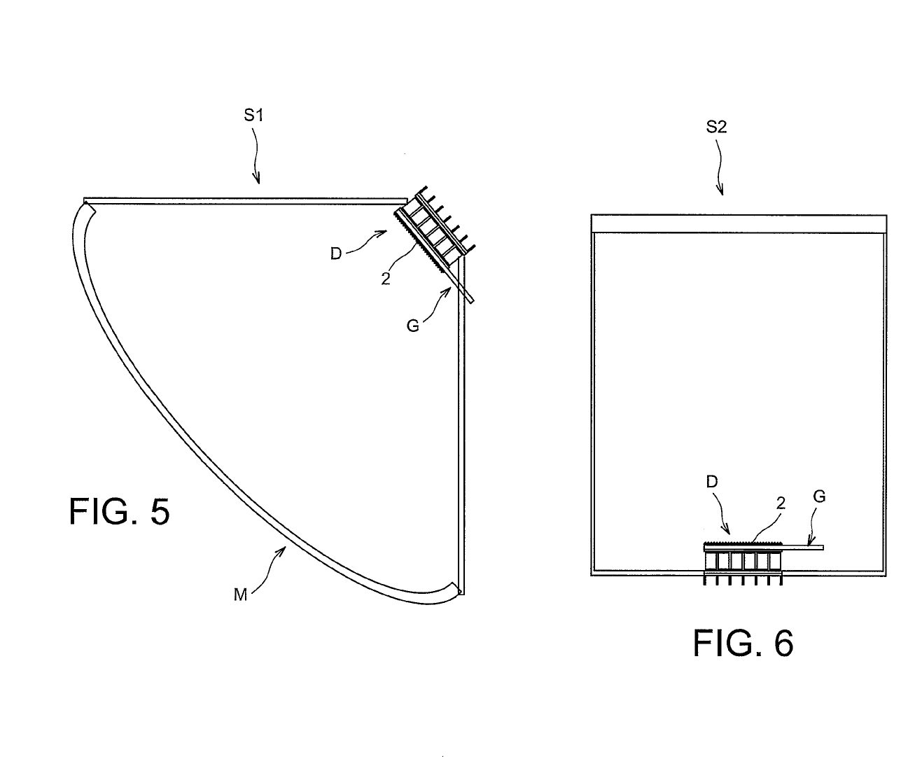

FIG. 5 shows an example of a solar system with concentration by mirrors comprising a device according to the invention.

System S1 comprises a concave mirror M and the device D is suspended facing the mirror, more particularly the reception face 2 of the device, such that the reception face receives the solar flux concentrated by the mirror M. A gas line G is provided for the input of combustion energy, either external according to the mode shown in FIG. 2, or internal according to the mode shown in FIG. 1.

FIG. 6 shows an example of a solar system with concentration by Fresnel lenses comprising a device according to the invention.

The system S2 comprises a box 26 at the bottom end of which there is a device D according to the invention, and the top end of which is formed from a Fresnel lens 30, concentrating solar flux on the reception face 2. The reception face is located at the focal point of the lens. The gas supply is denoted G.

For example, concentration factors are typically of the order of 500 to 2000.

Preferably, installations are made comprising several systems S1 and/or S2 to form all sizes and capacities of electricity generating units operating in hybrid mode. For example, the device may be mounted on lateral displacement means, for example on a slide so as to follow the solar concentration point for a given period of time. This means that the solar concentration device is only moved in long steps. The concentration zone of the light flux on the reception surface moves with the movement of the sun. It moves firstly on the receiving surface, and the device can then be moved along the slide to continue to receive light flux. After a period, displacement and defocusing are such that the entire module must be realigned facing the sun.

This realignment is made by a solar following device that collectively realigns all modules.

These systems are well known to those skilled in the art of photovoltaics by concentration. The position of the solar concentration point on the reception face may be monitored by temperature measurements under the reception face, i.e. in the body 14.

The surface area of the thermoelectric element and the surface area and thickness of the reception face are optimised as a function of the required temperatures and flux.

Examples of suitable materials for making a conversion device according to the invention are given below.

Elements 15, 114.1, 114.2, 215 may for example be made from silicon carbide SIC or SiSiC, or an inconel type metal or refractory steel, or ceramic oxide such as Cordierite, or Boron Nitride, etc.

These materials have a thermal conductivity of more than 50 W/mK.

The selective high temperature treatment may be:
A Solkote® type coating manufactured by SOLEC and adapted to temperatures below 500° C.:
TiAlN/SiO2 deposit deposited by vapour phase deposition adapted to temperatures of the order of 350° C. to 500° C.,
deposits or texturing of Mo, W . . . molybdenum, tungsten type refractory materials adapted to temperatures of more than 500° C.

Junctions in the thermoelectric generator may for example be made from:
Bi₂Te₃ for temperatures below 200° C.,
PbTe for temperatures of between 300° C. and 500° C.,
CoSb₃ for temperatures of between 500° C. and 600° C.,
SiGe for temperatures of between 600° C. and 1000° C.
Mg₂SiSn for temperatures of between 400° C. and 600° C.

Preferably, the coefficients of thermal expansion a of the different materials forming the interfaces, particularly in the part of the devices at high temperature, are preferably chosen to be similar to reduce thermomechanical stresses related to differences in coefficients of thermal expansion. Coefficients of thermal expansion are given between parentheses.

For example, in the case of an SiC (˜2.7×10⁻⁶ m·K⁻¹) type ceramic microreactor:
The selective treatment will preferably be textured Mo (4.8×10⁻⁶ m·K⁻¹) or textured W (4.5×10⁻⁶ m·K⁻¹),
the electrical insulating layer will preferably be made from AlN (4.5×10⁻⁶ M·K⁻¹) or alumina (5.4×10⁻⁶ m·K⁻¹) or cBN (2.7×10⁻⁶ m·K⁻¹) or wBN (2.7×10⁻⁶ m·K⁻¹),
connections between the thermoelectric junctions will preferably be made from Mo (4.8×10⁻⁶ m·K⁻¹).

In the case of a metal or refractory steel type alloy microreactor (α˜10 to 18×10⁻⁶ m·K⁻¹):
the selective treatment is preferably based on TiAlN or AlN,
the electrical insulating layer is made from AlN (4.5×10⁻⁶ m·K⁻¹) or alumina (5.4×10⁻⁶ m·K⁻¹) or cBN (2.7×10⁻⁶ m·K⁻¹) or wBN (2.7×10⁻⁶ m·K⁻¹),
connections between the thermoelectric junctions are made from Cu (17×10⁻⁶ m·K⁻¹) or Fe (12×10⁻⁶ m·K⁻¹).

It will be understood that these examples are not limitative, and other combinations of assemblies are possible. There are many assembly combinations due to the reduction of thermal stresses made possible using this invention.

With the hybrid solar device according to the invention, the reliability of the thermoelectric generator is improved because thermal cycling stresses are significantly reduced in the case of thermoelectric solar generators due to the possibility of working at a practically constant temperature without returning to ambient temperature every night. Therefore Interfaces, particularly between thermoelectric materials, interconnections and ceramic supports have a very much better reliability and a much longer lifespan.

The problem of intermittent sunshine is also solved. The device according to the invention enables continuous operation and generation of electricity even at night, and solves the problem of intermittence specific to solar energy due to its two operating modes, without making use of a storage technology. The device is also adaptable, by modifying the level of electricity generation as a function of the gas flow input into the combustion reactor.

The invention improves efficiencies by controlled management of the heat source.

The high temperature of the heat source (100-1000° C.), that is controllable due to the fuel flow input into the reactor, makes it possible to maximise the temperature difference between the heat source and the cold source and therefore to control and maximise the efficiency of the thermoelectric generators. For example, the conversion efficiency for a temperature of 500° C. on the hot face and a temperature difference of 300° C. between the hot face and the cold face a ZT=1, will be about 8%. This efficiency can be maintained throughout the day. Efficiencies can be more than 15% for higher temperature differences and for higher performance thermoelectric elements.

The efficiency is also further improved by controlled management of the cold source. Because a high temperature can be achieved and maintained on the hot face of the thermoelectric generator, the operating point of the device can be located to optimise the thermoelectric efficiency. For example, during the day when the ambient air temperature is high, for example 40° C., the operating point will be raised to work at a relatively high temperature of the cold source, for example 100° C., so as to assure good heat transfer from the heat sink to the atmosphere in continuous mode due to the high temperature difference relative to the environment. On the contrary, the operating point can be lowered at night or when heat transfer on the heat sinks is good due to wind, because external conditions are capable of removing heat from the cold source. This adaptation to environment conditions is possible due to the hybrid mode of the devices according to the invention.

What is claimed is:

1-18. (canceled)

19. Solar system comprising means of concentrating solar radiation and one solar device for generating electricity, said solar device for generating electricity comprising:
a face, called the reception face, that will receive a solar flux,
a thermoelectric generator, said thermoelectric generator comprising at least one thermoelectric module placed between a first face called the “hot face” and a second face called the “cold face”, said hot face being located on the same side as the reception face,
additional heat supplier to the hot face, said additional heat supplier being inserted at least partly between the reception face and the hot face of the thermoelectric generator, the additional heat supplier comprising an element comprising a first face in contact with the reception face and a second face in contact with the hot face of the thermoelectric generator, said additional heat supplier and the reception face being a hot source,
a controller of controlling said additional heat input means, so as to control temperature variations on the hot source.

20. Solar system for generation of electricity according to claim 19, in which the additional heat supplier comprises an element located between the reception face and the hot face, said element comprising a combustion chamber supplied with fuel.

21. Solar system for generation of electricity according to claim 20, in which the combustion chamber is provided with a combustion igniter or combustion is initiated in the combustion chamber directly by the high temperature generated by the solar flux.

22. Solar system for generation of electricity according to claim 20, in which the combustion chamber comprises channels extending parallel to the hot face of the thermoelectric generator and the reception face.

23. Solar system for generation of electricity according to claim 19, in which the additional heat supplier comprises an element located between the reception face and the hot face and provided at least with one channel connected to a combustion chamber supplied with fuel, said combustion chamber comprising a combustion igniter.

24. Solar system for generation of electricity according to claim 19, in which the additional heat input means comprise an element located between the reception face and the hot face and means of heating said element located outside the stack, said element being provided with an extension projecting laterally from the stack, said extension being designed to be heated by the heating means, the heat input to the hot face being transported by conduction.

25. Solar system for generation of electricity according to claim 24, comprising a heat insulator insulating the lateral extension.

26. Solar system for generation of electricity according to claim 20, comprising means of applying a tightening force at least between the element and the hot face so as to reduce thermal resistances.

27. Solar system for generation of electricity according to claim 19, in which the stack comprises a heat insulator between a hot zone of the device formed by the reception face, the additional heat supplier and the hot face and a cold zone formed by the cold face.

28. Solar system for generation of electricity according to claim 19, comprising heat dissipation means in contact with the cold face.

29. Solar system for generation of electricity according to claim 19, in which the reception face comprises a selective high temperature treatment.

30. Solar system for generation of electricity a according to claim 19, in which the additional heat input supplier comprises an element made from an electrical insulating material, the electrical connections of the thermoelectric generator being made directly on the element.

31. Solar system for generation of electricity according to claim 19, in which the element is made from silicon carbide, molybdenum or tungsten.

32. Solar system for generation of electricity according to claim 19, in which the fuel is hydrogen.

33. Solar system according to claim 19, in which the solar radiation concentration means consist of a mirror.

34. Solar system according to claim 19, in which the solar radiation concentration means consist of a Fresnel lens.

35. Solar system according to claim 19, comprising means of moving the solar electricity generation device, a temperature sensor for measuring the temperature of the reception face and a controller for controlling the displacement of the device such that the reception face is illuminated by the solar flux.
